(19) United States
(12) Patent Application Publication
(10) Pub. No.: US 2024/0264200 A1
(43) Pub. Date: Aug. 8, 2024

(54) CONTACT PROBE AND PROBE UNIT

(71) Applicant: NHK Spring Co., Ltd., Yokohama-shi (JP)

(72) Inventors: Kazuya Soma, Kanagawa (JP); Hajime Arai, Kanagawa (JP)

(73) Assignee: NHK Spring Co., Ltd., Yokohama-shi (JP)

(21) Appl. No.: 18/424,927

(22) Filed: Jan. 29, 2024

(30) Foreign Application Priority Data
Feb. 2, 2023 (JP) 2023-014708

(51) Int. Cl. G01R 1/067; G01R 1/073

(52) U.S. Cl. CPC G01R 1/06722; G01R 1/06738; G01R 1/07314

(57) ABSTRACT

A contact probe includes: a first plunger including a tip end configured to be contact with one of electrode, and a flange that is continuous to the tip end; and a coil spring configured to be joined to the first plunger. The tip end includes: a tip contact including a tip configured to be contact with the one of the electrode; a columnar first base portion provided to a base end side of the tip contact, and including a lateral side surface extending along a longitudinal axis of the first plunger; and a second base portion provided to an end of the first base portion, the end being on a side opposite to the tip contact, the second base portion including an inclined lateral side inclined in a manner approaching the longitudinal axis of the first plunger, as the inclined lateral side extends toward the flange.

This application is based upon and claims the benefit of priority of the prior Japanese Patent Application No. 2023-014708, filed on Feb. 2, 2023, the entire contents of which are incorporated herein by reference.

### BACKGROUND

The present disclosure relates to a contact probe and a probe unit.

In testing of the conduction or the characteristics of test targets, such as semiconductor integrated circuits or liquid crystal display devices, conductive contact probes have been used. Such a conductive contact probe is used in establishing an electrical connection between the test target and a signal processing device provided with a circuit board for outputting a test signal (see Japanese Patent No. 3742742, for example). In order to carry out tests of the conductions or the operation characteristics correctly, it is necessary to ensure reliability of inputs and outputs of test signals via the contact probe. In the contact probe disclosed in Japanese Patent No. 3742742, one end coming into contact with a plurality of test targets has a crown-like shape including a plurality of claws, and this crown-like shape is brought into contact with an electrode of the test targets.

### SUMMARY

Such an electrode provided to the test target is made of solder, for example, and sometimes its surface is covered with an oxide film. In such a case, a contact probe needs to break through the oxide film to come into contact with the electrode. However, merely with the crown-like shape disclosed in Japanese Patent No. 3742742, the contact probe sometimes fails to break through the oxide film, and electric conduction may become instable.

There is a need for a contact probe and a probe unit capable of stabilizing the conduction with a test target.

According to one aspect of the present disclosure, there is provided a contact probe for transmitting a signal by connecting longitudinal ends thereof to different electrodes, including: a first plunger including a tip end configured to be contact with one of the electrodes, and a flange that is continuous to the tip end; and a coil spring configured to be joined to the first plunger, wherein the tip end includes: a tip contact including a tip configured to be contact with the one of the electrode; a first base portion that is columnar, the first base portion being provided to a base end side of the tip contact, and including a lateral side surface extending along a longitudinal axis of the first plunger; and a second base portion provided to an end of the first base portion, the end being on a side opposite to the tip contact, the second base portion including an inclined lateral side inclined in a manner approaching the longitudinal axis of the first plunger, as the inclined lateral side extends toward the flange.

According to another aspect of the present disclosure, there is provided a probe unit including: a contact probe including: a first plunger including a tip end configured to be contact with one of electrodes, and a flange that is continuous to the tip end; and a coil spring connected to the first plunger; and a probe holder including a holder hole configured to hold the contact probe, wherein the tip end includes a tip contact including a tip configured to be contact with the one of the electrodes; a first base portion that is columnar, the first base portion being provided to a base end side of the tip contact, and including a lateral side surface extending along a longitudinal axis of the first plunger; and a second base portion provided to an end of the first base portion, the end being on a side opposite to the tip contact, and including an inclined lateral side inclined in a manner approaching the longitudinal axis of the first plunger, as the inclined lateral side extends toward the flange.

### BRIEF DESCRIPTION OF THE DRAWINGS

FIG. 1 is a perspective view illustrating a configuration of a probe unit according to one embodiment;

FIG. 2 is a cross-sectional view illustrating a structure of a relevant portion of the probe unit according to the embodiment;

FIG. 3 is a perspective view for explaining a structure of a first plunger included in the contact probe according to the embodiment;

FIG. 4 is a cross-sectional view illustrating a structure of a relevant portion of the probe unit at the time of test of a semiconductor integrated circuit;

FIG. 5 is a perspective view for explaining a structure of a first plunger included in a contact probe according to a first modification;

FIG. 6 is a schematic for explaining a structure of a first plunger included in a contact probe according to a second modification;

FIG. 7 is a schematic for explaining a structure of a first plunger included in a contact probe according to a third modification;

FIG. 8 is a schematic for explaining a structure of a relevant portion of a first plunger included in a contact probe according to a fourth modification;

FIG. 9 is a perspective view for explaining a structure of a first plunger included in a contact probe according to a fifth modification;

FIG. 10 is a schematic illustrating a structure of a tip end in the view from the arrow A in FIG. 9;

FIG. 11 is a schematic for explaining a structure of a first plunger included in a contact probe according to a sixth modification;

FIG. 12 is a perspective view for explaining a structure of a first plunger included in a contact probe according to a seventh modification; and

FIG. 13 is a schematic illustrating a structure of a tip end in the view from the arrow B in FIG. 12.

### DETAILED DESCRIPTION

An embodiment for carrying out the present disclosure will now be explained in detail with reference to the drawings. The embodiment is not intended to limit the scope of the present disclosure. Furthermore, the drawings referred to in the following description only provides schematic representations of shapes, sizes, and positional relations of a degree enabling understanding of the present invention, and therefore, the present disclosure is not limited to the shapes, the sizes, and the positional relations illustrated in the drawings.

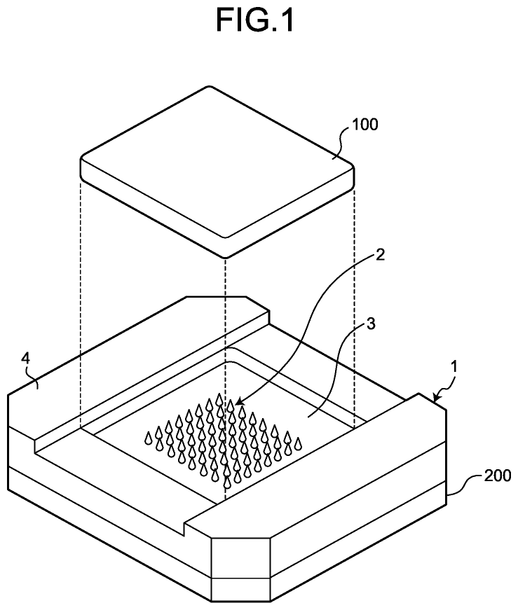

FIG. 1 is a perspective view illustrating a configuration of a probe unit according to one embodiment. This probe unit 1 illustrated in FIG. 1 is a device used in inspecting electric characteristics of a semiconductor integrated circuit 100 that is a test target, and is a device electrically connecting the semiconductor integrated circuit 100 and a circuit board 200 for outputting a test signal to the semiconductor integrated circuit 100.

The probe unit 1 includes: a conductive contact probe 2 (hereinafter simply referred to as a “probe 2”) longitudinal ends of which are to come into contact with an electrode of the semiconductor integrated circuit 100 and an electrode of circuit board 200 that are different two bodies, respectively; a probe holder 3 that houses to hold a plurality of probes 2 arranged in a predetermined pattern; a holder member 4 that is provided around the probe holder 3 and that suppresses a displacement of the semiconductor integrated circuit 100 coming into contact with the plurality of probes 2 during a test.

In this embodiment, the electrode of the semiconductor integrated circuit 100 is a ball grid array (BGA) made of solder. Without limitation to electrodes using solder, the present disclosure is also applicable to any terminals not using any solder, or terminals having a film formed on the surface. Examples other than a BGA include a quad flat package (QFP), a quad flat non-leaded (QFN) packages, a system-on-chip (SoC) terminal, and a terminal made of copper.

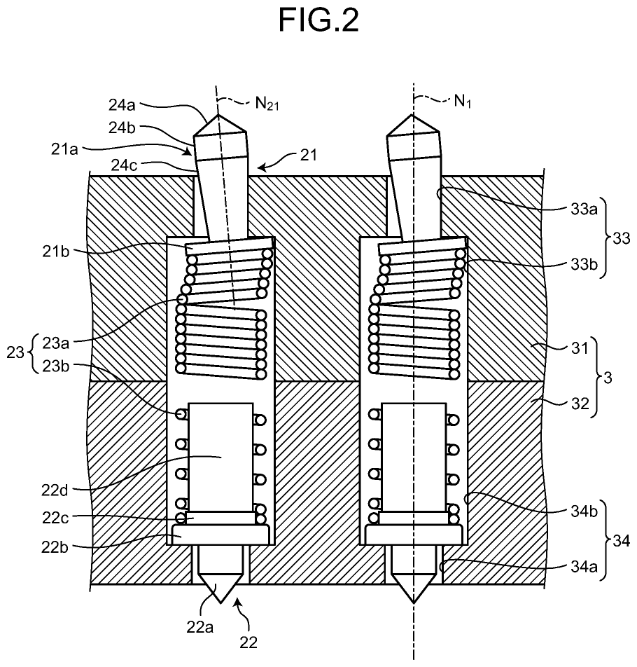

FIG. 2 is a cross-sectional view illustrating a structure of a relevant portion of the probe unit according to the embodiment. The probe 2 is made of a conductive material, and includes: a first plunger 21 that comes into contact with the electrode of a semiconductor integrated circuit 100, when the semiconductor integrated circuit 100 is to be inspected; a second plunger 22 that comes into contact with the electrode of the circuit board 200 provided with a test circuit; and a coil spring 23 that is provided between the first plunger 21 and the second plunger 22, and connects the first plunger 21 and the second plunger 22 in a manner enabled to advance and to retract. In FIG. 2, the first plunger 21 has a longitudinal axis N₂₁ of the first plunger 21 inclined with respect to an axis (longitudinal axis) N₁ of the probe 2. The second plunger 22 and the coil spring 23 share the same axial line. In other words, the central axes of the second plunger 22 and the coil spring 23 are both positioned along the axis (longitudinal axis) N₁ of the probe 2. The “same axial line” include some allowance such as a member-dependent deformation and a manufacturing error. With the coil spring 23 becoming extended and compressed in the axial line direction when the probe 2 comes into contact with the semiconductor integrated circuit 100, the probe 2 exerts a load on the semiconductor integrated circuit 100 and the circuit board 200, while alleviating the impact exerted on the electrode of the semiconductor integrated circuit 100.

The first plunger 21 has a tapered tip, and has a tip end 21a coming into contact with the electrode of the semiconductor integrated circuit 100, and a flange 21b having a larger diameter than that of the tip end 21a. The first plunger 21 is movable in the direction of the axial line by the extending and compressing action of the coil spring 23, and is biased toward the semiconductor integrated circuit 100 and brought into contact with the electrode of the semiconductor integrated circuit 100, by the biasing force of the coil spring 23. Hereinafter, the side of the first plunger 21 facing the semiconductor integrated circuit 100 will be referred to as a “tip end side”, and the side opposite to the tip end side in the direction of the longitudinal axis N₂₁ of the first plunger 21 will be referred to as a “base end side”.

In this embodiment, the tip end 21a will be described to have a conical tip, but may also have a tip in another shape, e.g., a crown-shaped tip having a plurality of claws, or a spherical tip.

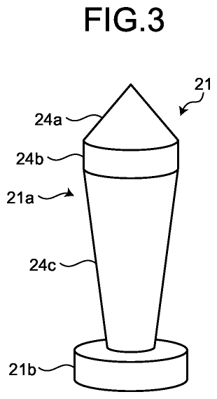

FIG. 3 is a perspective view for explaining a structure of the first plunger included in the contact probe according to the embodiment. The tip end 21a includes a tip contact 24a that has a circular conical shape and coming into contact with the electrode of the semiconductor integrated circuit 100, a cylindrical first base portion 24b that is provided to the base end side of the tip contact 24a, and a second base portion 24c that is provided to an end of the first base portion 24b on the side opposite to the tip contact 24a and that is coupled to the flange 21b. In the probe unit 1, the tip of the tip contact 24a is positioned offset from the longitudinal axis N₁.

The first base portion 24b has a side surface extending along the longitudinal axis N₂₁ of the first plunger 21.

The second base portion 24c has a truncated cone shape the diameter of which becoming smaller toward the flange 21b. In other words, the second base portion 24c has a lateral side surface inclined in a manner approaching the longitudinal axis N₂₁ toward the flange 21b. The distance from the side surface to the longitudinal axis N₂₁ becomes smaller toward the flange 21b.

The second plunger 22 has a tapered tip, and includes: a tip end 22a that comes into contact with the electrode of the circuit board 200; a flange 22b that has a larger diameter than that of the tip end 22a; a boss 22c that extends toward the side opposite to the tip end 22a with the flange 22b interposed therebetween, that has a diameter smaller than that of the flange 22b, and onto which the other end of the coil spring 23 is press-fitted; and a base end 22d that extends toward the side opposite to the flange 22b with the boss 22c interposed therebetween, and that has a diameter smaller than that of the boss 22c. The second plunger 22 is movable in the direction of the axial line by the extending and compressing action of the coil spring 23, and is biased toward the circuit board 200, and brought into contact with electrode of the circuit board 200 by the biasing force of the coil spring 23.

The second plunger 22 may also have a configuration not including the boss 22c and the base end 22d, in the same manner as the first plunger 21.

The coil spring 23 includes a closely wound portion 23a closely wound around the base end side of the first plunger 21, and a roughly wound portion 23b attached to the base end side of the second plunger 22 and wound at predetermined intervals. The coil spring 23 is winding of one conductive wire, for example. The coil spring 23 applies a load to the first plunger 21 in a direction inclined with respect to the direction of the axis N₁, and in a direction separating from the second plunger 22. For example, it is possible to give an inclination to the first plunger 21 by partly offsetting the center of the coil spring 23 (see FIG. 2) or by adjusting the intervals of the wire in such a manner that the end (the surface of the end turn) is inclined with respect to the longitudinal axis of the coil spring 23.

The inclination of the first plunger 21 with respect to the axis N₁ may be achieved not only by adjusting the characteristics of the coil spring 23 but also by making adjustments other than the characteristics of the coil spring 23, e.g., by installing a wedge between the flange 21b and an end of the coil spring 23 (the closely wound portion 23a).

An end of the closely wound portion 23a is joined to the base end side of the first plunger 21, for example. An end of the roughly wound portion 23b is press-fitted onto the base end of the second plunger 22 (the boss 22c). The probe 2 becomes extended and compressed in the axial line direction due to the extension and compression of the roughly wound portion 23b.

Explained in the embodiment is a configuration in which the coil spring 23 is joined to the first plunger 21, and the boss 22c of the second plunger 22 is inserted into the coil spring 23, but present disclosure is not limited thereto, and for example, the first plunger 21 and the coil spring 23 may be provided separately, instead of being joined to each other.

The probe holder 3 is made from an insulating material such as resin, machinable ceramic, or silicon, and a first member 31 positioned on the upper side in FIG. 2 and a second member 32 positioned on the lower side is stacked on top of each other. The first member 31 and the second member 32 have the same number of holder holes 33 and holder holes 34, respectively, for housing a plurality of the probes 2, respectively. Each of the holder holes 33 and the corresponding one of the holder holes 34 for housing a probe 2 are provided so as to have a matching axial line. The positions where the holder holes 33 and the holder holes 34 are formed are determined based on the wiring pattern of the semiconductor integrated circuit 100.

Each of the holder holes 33 and the holder holes 34 has a shape of a stepped hole having different diameters in penetrating direction. In other words, the holder hole 33 has a small diameter portion 33a having an opening on the top end surface of the probe holder 3, and a large diameter portion 33b having a larger diameter than that of the small diameter portion 33a. The holder hole 34 also has a small diameter portion 34a having an opening on the bottom end surface of the probe holder 3, and a large diameter portion 34b having a larger diameter than that of the small diameter portion 34a. The shapes of these holder holes 33 and 34 are determined based on the structure of the probe 2 to be housed. The flange 21b of the first plunger 21 abuts against a wall surface on the border between the small diameter portion 33a and the large diameter portion 33b of the holder hole 33, to serve a function for preventing disengagement of the probe 2 from the probe holder 3. The flange 22b of the second plunger 22 also abuts against the wall surface on the border between the small diameter portion 34a and the large diameter portion 34b of the holder hole 34, to serve a function for preventing disengagement of the probe 2 form the probe holder 3.

With the probe 2 housed in the probe holder 3, and without any load exerted on the tip end 21a, 22a (see FIG. 2), the flange 21b of the first plunger 21 is in abutment against the step portion formed by the small diameter portion 33a and the large diameter portion 33b of the holder hole 33, and the second base portion 24c is in contact with a wall surface of the small diameter portion 33a. The second base portion 24c is kept in contact with the wall surface of the small diameter portion 33a by the biasing force of the coil spring 23, and the side surface of the second base portion 24c is in linear contact with the wall surface of the small diameter portion 33a. Therefore, the longitudinal axis N₂₁ of the first plunger 21 is inclined with respect to the axis N₁ of the probe 2. At this time, the first base portion 24b is positioned outside of the probe holder 3.

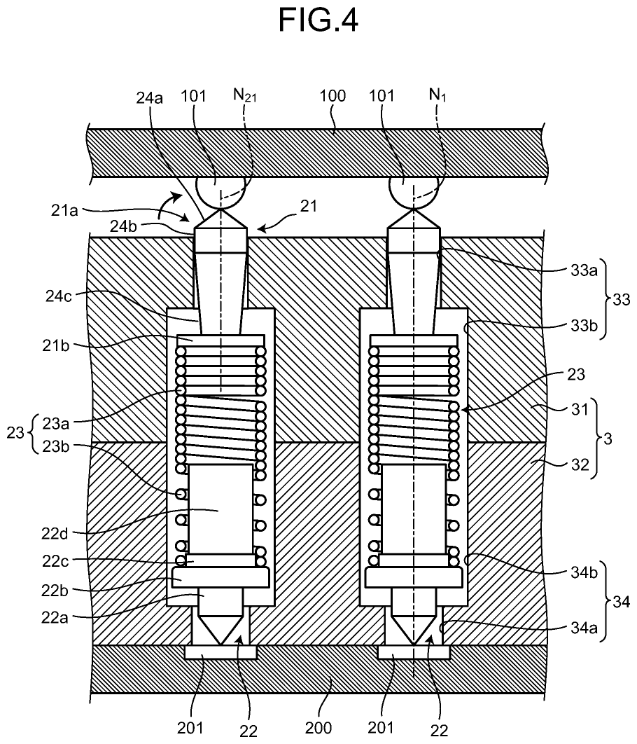

FIG. 4 is a schematic illustrating a configuration during a test of the semiconductor integrated circuit 100 using the probe holder 3. During the test of the semiconductor integrated circuit 100, due to a contact load from the semiconductor integrated circuit 100 and the circuit board 200, the coil spring 23 is compressed in the longitudinal direction. The circuit board 200 outputs a test signal to be supplied to the semiconductor integrated circuit 100 from the electrode 201 of the circuit board 200 during the test. The test signal passes through the second plunger 22, the closely wound portion 23a, and the first plunger 21 of the probe 2, and reaches a connecting electrode 101 of the semiconductor integrated circuit 100.

A behavior of the first plunger 21 at the time when the tip end 21a comes into contact with the connecting electrode 101 (BGA) will now be explained. When the probe 2 (roughly wound portion 23b) becomes compressed by receiving the loads from the connecting electrode 101 and the electrode 201, the first plunger 21 goes into the holder hole 33. At this time, a portion in contact with the small diameter portion 33a transitions from the second base portion 24c to the first base portion 24b of the tip end 21a. At the timing at which the portion in contact with the small diameter portion 33a transitions from the second base portion 24c to the first base portion 24b, the first plunger 21 is caused to rotate in a direction in which the longitudinal axis N₂₁ moves closer to being in parallel with the axis N₁. By this rotation, the position of the tip of the tip contact 24a is caused to move, and the tip contact 24a scrapes off the surface of the connecting electrode 101, and breaks through the oxide film or the like. As a result, the tip contact 24a breaks through the oxide film or the like formed on the surface of the connecting electrode 101, and comes into contact with the surface of the connecting electrode 101.

By contrast, a known plunger is not inclined with respect to the axis N while there is no load exerted from the test target, and the longitudinal axis (corresponding to the longitudinal axis N₂₁) is matched with the axis N and the plunger. Therefore, the plunger advances and retracts along the direction of the axis N. In the known configuration, the plunger comes into contact with the test target not in rotation, as in the first plunger 21 according to the embodiment. Therefore, sometimes the plunger fails to break through the oxide film on the surface of the electrode.

In the embodiment described above, the first plunger 21 is provided with a side surface extending in parallel with the axis N₁, and a side surface inclined with respect to the axis N₁, and, upon coming into contact with the test target, the first plunger 21 is rotated so as to break through the oxide film formed on the surface of the test target. According to this embodiment, it is possible to stabilize the electric conduction with the test target.

Furthermore, according to the embodiment, upon coming into contact with the test target, the longitudinal axis N₂₁ of the first plunger 21 is controlled to become in parallel with the axis N₁, using the wall surface of the tip end 21a and the inner wall of the holder hole. Therefore, it is possible to improve the positional precision of the tip of the tip contact 24a, using a simple structure.

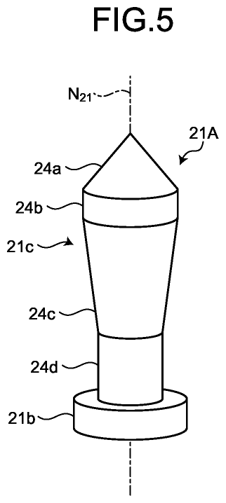

A first modification of the embodiment will now be explained with reference to FIG. 5. FIG. 5 is a perspective view for explaining a structure of a first plunger included in a contact probe according to a first modification. The first modification has the structure that is the same as that according to the embodiment, except that the structure of the first plunger is different. Elements that are the same as those in the embodiment are given the same reference numerals.

A first plunger 21A according to the first modification has a tapered tip, and includes a tip end 21c coming into contact with the electrode of the semiconductor integrated circuit 100, and the flange 21b having a larger diameter than that of the tip end 21c.

The tip end 21c includes the tip contact 24a that has a circular conical shape and coming into contact with the electrode of the semiconductor integrated circuit 100, the cylindrical first base portion 24b that is provided to the base end side of the tip contact 24a, the second base portion 24c that is provided to the end of the first base portion 24b on the side opposite to the tip contact 24a, the cylindrical third base portion 24d that is provided to the second base portion 24c on the side opposite to the first base portion 24b and that is coupled to the flange 21b. The tip end 21c has a structure of the tip end 21a further including a third base portion 24d. The diameter of the third base portion 24d is equal to or smaller than that of the first base portion 24b.

In the first modification, when the tip end 21c and the connecting electrode 101 come into contact with each other, the portion in contact with the small diameter portion 33a transitions from the second base portion 24c to the first base portion 24b of the tip end 21c. At the timing at which the portion in contact with the small diameter portion 33a transitions from the second base portion 24c to the first base portion 24b, the first plunger 21A is caused to rotate, and the longitudinal axis (corresponding to longitudinal axis N₂₁) becomes in parallel or matched with the axis N₁ (see FIG. 2, for example). By this rotation, the tip contact 24a scrapes off the surface of the connecting electrode 101, and breaks through the oxide film or the like.

By contrast, by configuring the portion in contact with the small diameter portion 33a to transition from the first base portion 24b of the tip end 21c, through the second base portion 24c, and to the third base portion 24d, when the tip end 21c separates from and is brought out of contact with the connecting electrode 101, the first plunger 21A is rotated at the timing at which the portion in contact with the small diameter portion 33a transitions from the second base portion 24c to the first base portion 24b. In this configuration, the longitudinal axis N₂₁ of the first plunger 21A becomes parallel or matched with the axis N₁ (see FIG. 2, for example), because the third base portion 24d has a cylindrical shape. Because the probes 2 extend substantially perpendicularly from the outer surface of the holder 3, it is possible to suppress interference between adjacent probes, due to their inclinations, for example. Explained herein is an example in which the lateral side surface of the third base portion 24d is in parallel with the longitudinal axis N₂₁, but the inclination angle of the longitudinal axis N₂₁ may also be set to a degree not causing the interference between the probes, for example.

In the first modification explained above, the first plunger 21A is provided with a lateral side surface extending in parallel with the axis N₁, and another lateral surface inclined with respect to the axis N₁, so that the first plunger 21 is caused to rotate and to break through the oxide film formed on the surface of the test target, upon coming into contact with the test target. According to the first modification, it is possible to stabilize the electric conduction with the test target.

In the first modification, by providing the third base portion 24d in the first plunger 21A, it is possible to adjust the length of the second base portion 24c in the direction of the longitudinal axis N₂₁, and to adjust the degree by which the tip of the first plunger 21A is rotated.

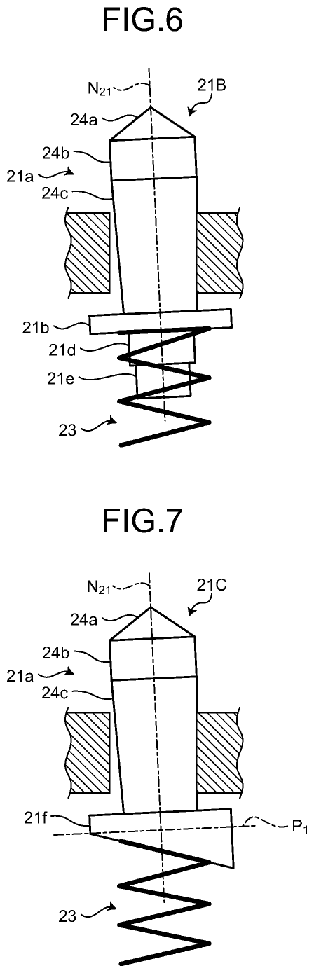

A second modification of the embodiment will now be explained with reference to FIG. 6. FIG. 6 is a schematic for explaining a structure of a first plunger included in a contact probe according to the second modification. The second modification has the structure that is the same as that according to the embodiment, except that the structure of the first plunger is different. Elements that are the same as those in the embodiment are given the same reference numerals. In FIG. 6, the coil spring 23 is illustrated in a simplified manner.

A first plunger 21B according to the second modification has a tapered tip, and includes the tip end 21a that comes into contact with the electrode of the semiconductor integrated circuit 100, the flange 21b that has a larger diameter than that of the tip end 21a, a boss 21d that has a diameter smaller than that of the flange 21b, that extends toward the side opposite to the tip end 21a, with the flange 21b interposed therebetween, and that is press-fitted into one end of the coil spring 23, and a base tip end 21e that extend toward the side opposite to the flange 21b, with the boss 21d interposed therebetween, and that has a diameter smaller than that of the boss 21d.

In the second modification, one end of the closely wound portion 23a (see FIG. 2, for example) is joined to the boss 21d of the first plunger 21B, with any one or both of the winding force of the spring and soldering, for example, and in abutment against the flange 21b. With the boss 21d being thus fitted, the first plunger 21B and the coil spring 23 are joined to each other.

In the first plunger 21B, without any load exerted on the tip end 21a (see FIG. 2), the flange 21b is in abutment against the step portion formed by the small diameter portion 33a and the large diameter portion 33b of the holder hole 33, and the second base portion 24c is in contact with the wall surface of the small diameter portion 33a. At this time, the longitudinal axis N₂₁ of the first plunger 21B is inclined with respect to the axis N₁ of the probe. When the tip end 21a and the connecting electrode 101 come into contact with each other, the portion in contact with the small diameter portion 33a transitions from the second base portion 24c to the first base portion 24b of the tip end 21a. At the timing at which the portion in contact with the small diameter portion 33a transitions from the second base portion 24c to the first base portion 24b, the first plunger 21B is caused to rotate, and the longitudinal axis N₂₁ becomes in parallel or matched with the axis N₁ (see FIG. 2, for example). By this rotation, the tip contact 24a scrapes off the surface of the connecting electrode 101, and breaks through the oxide film or the like.

In the second modification explained above, the first plunger 21B is provided with a lateral side surface extending in parallel with the axis N₁, and another lateral surface inclined with respect to the axis N₁, so that the first plunger 21B is caused to rotate and to break through the oxide film formed on the surface of the test target, upon coming into contact with the test target, in the same manner as in the embodiment. According to the second modification, it is possible to stabilize the electric conduction with the test target.

A third modification of the embodiment will now be explained with reference to FIG. 7. FIG. 7 is a schematic for explaining a structure of a first plunger included in a contact probe according to the third modification. The third modification has the structure that is the same as that according to the embodiment, except that the structure of the first plunger is different. Elements that are the same as those in the embodiment are given the same reference numerals. In FIG. 7, too, the coil spring 23 is illustrated in a simplified manner.

A first plunger 21C according to the third modification has a tapered tip, and includes the tip end 21a coming into contact with the electrode of the semiconductor integrated circuit 100, and a flange 21f having a larger diameter than that of the tip end 21a. The flange 21f has an end surface inclined with respect to a plane P₁ perpendicularly intersecting with the longitudinal axis N₂₁, on the side opposite to the tip end 21a, that is, on the side to which the coil spring 23 is connected. The end surface thus intersects with the longitudinal axis N₂₁ at a non-perpendicular angle. Therefore, with the biasing force of the coil spring 23, it is possible to achieve a configuration in which the longitudinal axis N₂₁ is caused to incline with respect to the axis N₁ more actively, than in the first plunger 21 and the like.

In the third modification, one end of the closely wound portion 23a (see FIG. 2, for example) is joined to the boss 21d of the first plunger 21C, with any one or both of the winding force of the spring and soldering, for example, and in abutment against the flange 21b. With the boss 21d being thus fitted, the first plunger 21C and the coil spring 23 are joined to each other.

In the first plunger, without any load exerted on the tip end 21a (see FIG. 2), the flange 21b is in abutment against the step portion formed by the small diameter portion 33a and the large diameter portion 33b of the holder hole 33, and the second base portion 24c is in contact with the wall surface of the small diameter portion 33a. At this time, the longitudinal axis N₂₁ of the first plunger is inclined with respect to the axis N₁ of the probe. When the tip end 21a and the connecting electrode 101 come into contact with each other, the portion in contact with the small diameter portion 33a transitions from the second base portion 24c to the first base portion 24b of the tip end 21a. At the timing at which the portion in contact with the small diameter portion 33a transitions from the second base portion 24c to the first base portion 24b, the first plunger 21C is caused to rotate, and the longitudinal axis (corresponding to longitudinal axis N₂₁) becomes in parallel or matched with the axis N₁ (see FIG. 2, for example). By this rotation, the tip contact 24a scrapes off the surface of the connecting electrode 101, and breaks through the oxide film or the like.

In the third modification explained above, the first plunger 21C is provided with a lateral side surface extending in parallel with the axis N₁, and another lateral surface inclined with respect to the axis N₁, so that the first plunger 21C is caused to rotate and to break through the oxide film formed on the surface of the test target, upon coming into contact with the test target, in the same manner as in the embodiment. According to the third modification, it is possible to stabilize the electric conduction with the test target.

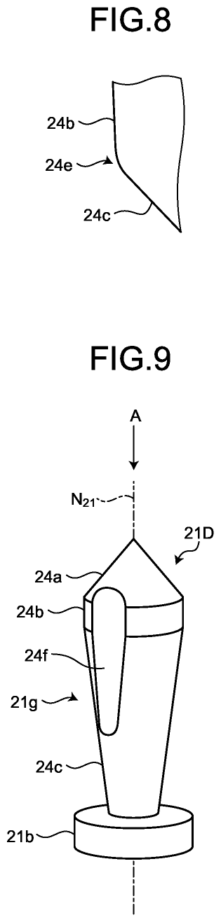

A fourth modification of the embodiment will now be explained with reference to FIG. 8. FIG. 8 is a schematic for explaining a structure of a relevant portion of a first plunger included in a contact probe according to the fourth modification. The fourth modification has the structure that is the same as that according to the embodiment, except that a specific example of the structure of the relevant portion of the first plunger is provided. Elements that are the same as those in the embodiment are given the same reference numerals.

In the first plunger according to the fourth modification, the tip end 21a has a connection surface 24e that connects the first base portion 24b and the second base portion 24c, and that delineates a smooth curved surface. By adjusting the curvature radius of the curved surface, it is possible to adjust the rotational speed of the first plunger 21 during the transition between the first base portion 24b and the second base portion 24c.

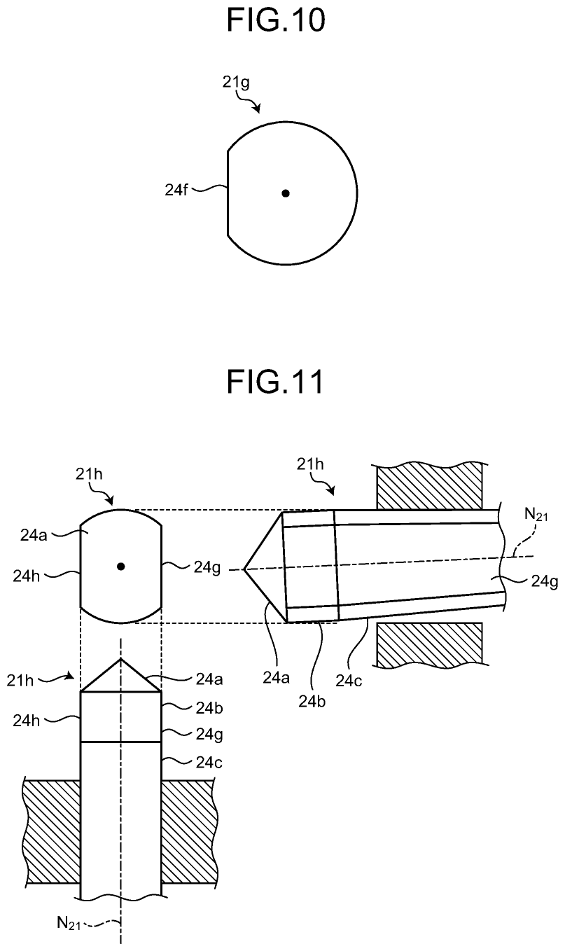

A fifth modification of the embodiment will now be explained with reference to FIGS. 9 and 10. FIG. 9 is a perspective view for explaining a structure of a first plunger included in a contact probe according to the fifth modification. FIG. 10 is a schematic illustrating a structure of a tip end in the view from the arrow A in FIG. 9. The fifth modification has the structure that is the same as that according to the embodiment, except that the structure of the first plunger is different. Elements that are the same as those in the embodiment are given the same reference numerals.

A first plunger 21D according to the fifth modification has a tapered tip, and includes a tip end 21g coming into contact with the electrode of the semiconductor integrated circuit 100, and the flange 21b having a larger diameter than that of the tip end 21g.

The tip end 21g includes the tip contact 24a that has a circular conical shape and coming into contact with the electrode of the semiconductor integrated circuit 100, the cylindrical first base portion 24b that is provided to the base end side of the tip contact 24a, and the second base portion 24c that is provided to the end of the first base portion 24b on the side opposite to the tip contact 24a. The tip end 21g also has a cutout portion 24f that is a cutout provided across a part of the tip end 21g, extending from the tip contact 24a to the second base portion 24c along the direction of the longitudinal axis N₂₁. The cutout portion 24f forms a flat surface.

In the first plunger 21D, without any load exerted on the tip end 21g (see FIG. 2), the flange 21b is in abutment against the step portion formed by the small diameter portion 33a and the large diameter portion 33b of the holder hole 33, and the second base portion 24c is in contact with the wall surface of the small diameter portion 33a. At this time, the longitudinal axis N₂₁ of the first plunger 21D is inclined with respect to the axis N₁ of the probe. When the tip end 21g and the connecting electrode 101 come into contact with each other, the portion in contact with the small diameter portion 33a transitions from the second base portion 24c to the first base portion 24b of the tip end 21g. At the timing at which the portion in contact with the small diameter portion 33a transitions from the second base portion 24c to the first base portion 24b, the first plunger 21D is caused to rotate, and the longitudinal axis N₂₁ becomes in parallel or matched with the axis N₁ (see FIG. 2, for example). By this rotation, the tip contact 24a scrapes off the surface of the connecting electrode 101, and breaks through the oxide film or the like.

The tip end 21g also has the cutout portion 24f, and this cutout surface comes into direct contact with the holder hole 33 (small diameter portion 33a), so that the rotation of the first plunger 21D about the longitudinal axis N₂₁ is suppressed. By suppressing the rotation of the first plunger 21D about the longitudinal axis N₂₁, it is possible to establish the direction of the movement of the tip contact 24a of the first plunger 21D during the transition from the second base portion 24c to the first base portion 24b.

In the fifth modification explained above, the first plunger 21D is provided with a lateral side surface extending in parallel with the axis N₁, and another lateral surface inclined with respect to the axis N₁, so that the first plunger 21D is caused to rotate and to break through the oxide film formed on the surface of the test target, upon coming into contact with the test target, in the same manner as in the embodiment. According to the fifth modification, it is possible to stabilize the electric conduction with the test target.

A sixth modification of the embodiment will now be explained with reference to FIG. 11. FIG. 11 is a schematic for explaining a structure of a first plunger included in a contact probe according to the sixth modification. The sixth modification has the structure that is the same as that according to the embodiment, except that the structure of the first plunger is different. Elements that are the same as those in the embodiment are given the same reference numerals.

The first plunger according to the sixth modification has a tapered tip, and includes a tip end 21h coming into contact with the electrode of the semiconductor integrated circuit 100, and the flange 21b having a larger diameter than that of the tip end 21h (see FIG. 2, for example).

The tip end 21h includes the tip contact 24a that has a circular conical shape and coming into contact with the electrode of the semiconductor integrated circuit 100, the cylindrical first base portion 24b that is provided to the base end side of the tip contact 24a, and the second base portion 24c that is provided to the end of the first base portion 24b on the side opposite to the tip contact 24a. The tip end 21h also has cutout portions 24g, 24h that are cutouts provided across parts of the tip end 21h, respectively, extending from the tip contact 24a to the second base portion 24c along the direction of the longitudinal axis N₂₁. These cutout portions 24g, 24h are provided on the side opposite to each other, with respect to the longitudinal axis N₂₁. Each of the cutout portions 24g, 24h forms a flat surface.

In the first plunger, without any load exerted on the tip end 21h (see FIG. 2), the flange 21b is in abutment against the step portion formed by the small diameter portion 33a and the large diameter portion 33b of the holder hole 33, and the second base portion 24c is in contact with the wall surface of the small diameter portion 33a. At this time, the longitudinal axis N₂₁ of the first plunger is inclined with respect to the axis N₁ of the probe. When the tip end 21h and the connecting electrode 101 come into contact with each other, the portion in contact with the small diameter portion 33a transitions from the second base portion 24c to the first base portion 24b of the tip end 21h. At the timing at which the portion in contact with the small diameter portion 33a transitions from the second base portion 24c to the first base portion 24b, the first plunger is caused to rotate, and the longitudinal axis N₂₁ becomes in parallel or matched with the axis N₁ (see FIG. 2, for example). By this rotation, the tip contact 24a scrapes off the surface of the connecting electrode 101, and breaks through the oxide film or the like.

The tip end 21h also has the cutout portions 24g, 24h, and these cutout surfaces come into direct contact with the holder hole 33 (small diameter portion 33a), so that the rotation of the first plunger about the longitudinal axis N₂₁ is suppressed. By suppressing the rotation of the first plunger about the longitudinal axis N₂₁, it is possible to establish the direction of the movement of the tip contact 24a of the first plunger during the transition from the second base portion 24c to the first base portion 24b.

In the sixth modification explained above, the first plunger is provided with a lateral side surface extending in parallel with the axis N₁, and another lateral surface inclined with respect to the axis N₁, so that the first plunger is caused to rotate and to break through the oxide film formed on the surface of the test target, upon coming into contact with the test target, in the same manner as in the embodiment. According to the sixth modification, it is possible to stabilize the electric conduction with the test target.

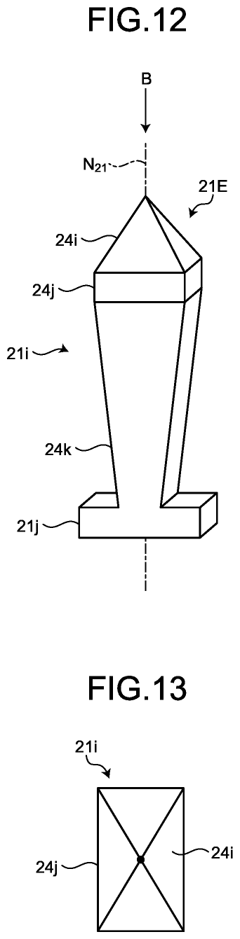

A seventh modification of the embodiment will now be explained with reference to FIGS. 12 and 13. FIG. 12 is a perspective view for explaining a structure of a first plunger included in a contact probe according to the seventh modification. FIG. 13 is a schematic illustrating a structure of a tip end in the view from the arrow B in FIG. 12. The seventh modification has the structure that is the same as that according to the embodiment, except that the structure of the first plunger is different. Elements that are the same as those in the embodiment are given the same reference numerals.

This first plunger 21E according to the seventh modification has a tapered tip, and includes a tip end 21i coming into contact with the electrode of the semiconductor integrated circuit 100, and a flange 21j having a larger diameter than that of the tip end 21i.

The tip end 21i includes a tip contact 24i that has a rectangular conical shape and coming into contact with the electrode of the semiconductor integrated circuit 100, a first base portion 24j that has a prism-like shape and is provided to the base end side of the tip contact 24i, and a second base portion 24k that is provided to the end of the first base portion 24j on the side opposite to the tip contact 24i and that is coupled to the flange 21j. The second base portion 24k has a truncated pyramidal shape with a cross-sectional size becoming smaller toward the flange 21j, with a plane orthogonal to the longitudinal axis N₂₁ as a sectional plane. In other words, the second base portion 24k is formed by a plurality of planes inclined with respect to the longitudinal axis N₂₁.

The tip end 21i may further include a prismatic third base, which corresponds to the third base portion 24d.

The flange portion 21j has a prism-like shape, is housed in the large diameter portion 33b, and is engaged in the small diameter portion 33a.

In the first plunger 21E, without any load exerted on the tip end 21i (see FIG. 2), the flange 21j is in abutment against the step portion formed by the small diameter portion 33a and the large diameter portion 33b of the holder hole 33, and the second base portion 24k is in contact with the wall surface of the small diameter portion 33a. At this time, the longitudinal axis N₂₁ of the first plunger 21E is inclined with respect to the axis N₁ of the probe. When the tip end 21i and the connecting electrode 101 come into contact with each other, the portion in contact with the small diameter portion 33a transitions from the second base portion 24k to the first base portion 24j of the tip end 21i. At the timing at which the portion in contact with the small diameter portion 33a transitions from the second base portion 24k to the first base portion 24j, the first plunger 21E is caused to rotate, and the longitudinal axis N₂₁ becomes in parallel or matched with the axis N₁ (see FIG. 2, for example). By this rotation, the tip contact 24a scrapes off the surface of the connecting electrode 101, and breaks through the oxide film or the like.

The tip end 21i is formed by flat surfaces, and these flat surfaces come into direct contact with the holder hole 33 (small diameter portion 33a), so that the rotation of the first plunger 21E about the longitudinal axis N₂₁ is suppressed. By suppressing the rotation of the first plunger 21E about the longitudinal axis N₂₁, it is possible to establish the direction of the movement of the tip contact 24a of the first plunger 21E during the transition from the second base portion 24k to the first base portion 24j.

In the seventh modification explained above, the first plunger 21E is provided with a lateral side surface extending in parallel with the axis N₁, and another lateral surface inclined with respect to the axis N₁, so that the first plunger 21E is caused to rotate and to break through the oxide film formed on the surface of the test target, upon coming into contact with the test target, in the same manner as in the embodiment. According to the seventh modification, it is possible to stabilize the electric conduction with the test target.

Although an embodiment for carrying out the present disclosure has been described above, the embodiment described above is not intended to limit the scope of the present disclosure in any way. The structure of the probe 2 described in the embodiment is merely exemplary, and it is possible to use the alloy material described above to various types of probes having been known. For example, the probe is not limited to those including a plunger and a coil spring as described above, but as long as the first plunger may be inclined, the present disclosure may be applied to a probe with a pipe member, a pogo pin, a wire probe that bends a wire into a bow-like shape to obtain a load, or a connecting terminal (connector) that connects electrical contacts to each other.

In this manner, the present disclosure may include various embodiments and the like not described herein, and various changes in design and the like may be made within the scope not departing from the technical concept defined by the claims.

As explained above, the contact probe and the probe unit according to the present disclosure are suitable for stabilizing the electrical conduction with an electrode of a test target.

According to the present disclosure, it is possible to stabilize the electric conduction with the test target, advantageously.

All examples and conditional language recited herein are intended for pedagogical purposes of aiding the reader in understanding the disclosure and the concepts contributed by the inventor to further the art, and are not to be construed as limitations to such specifically recited examples and conditions, nor does the organization of such examples in the specification relate to a showing of the superiority and inferiority of the disclosure. Although the embodiment has been described in detail, it should be understood that the various changes, substitutions, and alterations could be made hereto without departing from the spirit and scope of the disclosure.

What is claimed is:

1. A contact probe for transmitting a signal by connecting longitudinal ends thereof to different electrodes, comprising:
a first plunger including
a tip end configured to be contact with one of the electrodes, and
a flange that is continuous to the tip end; and
a coil spring configured to be joined to the first plunger, wherein
the tip end includes:
a tip contact including a tip configured to be contact with the one of the electrode;
a first base portion that is columnar, the first base portion being provided to a base end side of the tip contact, and including a lateral side surface extending along a longitudinal axis of the first plunger; and
a second base portion provided to an end of the first base portion, the end being on a side opposite to the tip contact, the second base portion including an inclined lateral side inclined in a manner approaching the longitudinal axis of the first plunger, as the inclined lateral side extends toward the flange.

2. The contact probe according to claim 1, wherein the tip end further includes a third base portion that is columnar, the third base portion being provided to the second base portion on a side opposite to the first base portion, and joined to the flange.

3. The contact probe according to claim 1, wherein the tip end includes a cutout portion provided across a part of the end from the tip contact to the second base portion, the cutout portion extending along a direction of the longitudinal axis of the first plunger.

4. The contact probe according to claim 1, wherein
the first base portion has a cylindrical shape, and
the second base portion has a truncated cone shape.

5. The contact probe according to claim 1, wherein
the first base portion has a prism-like shape, and
the second base portion has a truncated pyramidal shape.

6. The contact probe according to claim 1, wherein the flange includes a surface inclined with respect to a plane perpendicularly intersecting with the longitudinal axis of the first plunger, the surface being a surface on a side to which the coil spring is connected.

7. A probe unit comprising:
a contact probe including:
a first plunger including
a tip end configured to be contact with one of electrodes, and
a flange that is continuous to the tip end; and
a coil spring connected to the first plunger; and
a probe holder including a holder hole configured to hold the contact probe, wherein
the tip end includes
a tip contact including a tip configured to be contact with the one of the electrodes;
a first base portion that is columnar, the first base portion being provided to a base end side of the tip contact, and including a lateral side surface extending along a longitudinal axis of the first plunger; and
a second base portion provided to an end of the first base portion, the end being on a side opposite to the tip contact, and including an inclined lateral side inclined in a manner approaching the longitudinal axis of the first plunger, as the inclined lateral side extends toward the flange.
